(19) United States
(12) Patent Application Publication
(10) Pub. No.: US 2025/0300101 A1
(43) Pub. Date: Sep. 25, 2025

(54) ELECTRONIC DEVICE

(71) Applicant: Rohm Co., Ltd., Kyoto-shi (JP)

(72) Inventor: Hirofumi TAKEDA, Kyoto-shi (JP)

(21) Appl. No.: 19/230,952

(22) Filed: Jun. 6, 2025

Related U.S. Application Data
(63) Continuation of application No. PCT/JP2023/042664, filed on Nov. 29, 2023.

(30) Foreign Application Priority Data
Dec. 13, 2022 (JP) 2022-198666

(51) Int. Cl. H01L 23/60; H01L 21/56; H01L 23/00; H01L 23/31; H01L 23/495; H01L 23/498; H01L 25/16

(52) U.S. Cl. CPC H01L 23/60; H01L 23/49548; H01L 23/49838; H01L 24/32; H01L 25/16; H01L 21/56; H01L 23/3121; H01L 2224/32245; H01L 2924/19011

(57) ABSTRACT

An electronic device includes a wiring layer, an electronic element conductively bonded to the wiring layer, and a sealing resin covering the electronic element. The sealing resin includes a top surface facing in a first direction and located opposite to the wiring layer with respect to the electronic element in the first direction. The electronic device further includes a pillar extending in the first direction and electrically connected to the wiring layer, and a shield covering at least a portion of the top surface and electrically connected to the pillar. The pillar includes a peripheral surface facing in a direction orthogonal to the first direction and a connection surface facing a same side as the top surface in the first direction. The peripheral surface is covered with the sealing resin. The connection surface is in contact with the shield.

### TECHNICAL FIELD

The present disclosure relates to an electronic device.

### BACKGROUND ART

JP-A-2020-77694 discloses an example of an electronic device that includes a semiconductor element (HEMT) having a horizontal structure. The semiconductor element has a first electrode and a second electrode. In the electronic device, the semiconductor element is bonded to a die pad. The first electrode and the second electrode are electrically connected to a plurality of terminal leads located around the die pad via wires.

In the electronic device disclosed in JP-A-2020-77694, transmission of high-frequency electrical signals may be required to achieve more efficient power conversion. For this purpose, it is necessary to reduce external noise that can affect the driving of the semiconductor element while responding to the existing demand for miniaturization of the electronic device. Moreover, the noise generated by the driving of the semiconductor element may affect external peripheral devices. Therefore, it is required to reduce both external noise and the noise generated by the driving of the semiconductor element.

### BRIEF DESCRIPTION OF THE DRAWINGS

FIG. 1 is a plan view of an electronic device according to a first embodiment of the present disclosure.

FIG. 2 is a plan view corresponding to FIG. 1, in which a semiconductor element and a sealing resin are transparent.

FIG. 3 is a bottom view of the electronic device shown in FIG. 1.

FIG. 4 is a sectional view taken along line IV-IV in FIG. 2.

FIG. 5 is a sectional view taken along line V-V in FIG. 2.

FIG. 6 is a sectional view taken along line VI-VI in FIG. 2.

FIG. 7 is a partial enlarged sectional view of FIG. 4.

FIG. 8 is a sectional view illustrating a manufacturing step of the electronic device shown in FIG. 1.

FIG. 9 is a sectional view illustrating a manufacturing step of the electronic device shown in FIG. 1.

FIG. 10 is a sectional view illustrating a manufacturing step of the electronic device shown in FIG. 1.

FIG. 11 is a sectional view illustrating a manufacturing step of the electronic device shown in FIG. 1.

FIG. 12 is a sectional view illustrating a manufacturing step of the electronic device shown in FIG. 1.

FIG. 13 is a partial enlarged sectional view illustrating a manufacturing step of the electronic device shown in FIG. 1.

FIG. 14 is a partial enlarged sectional view illustrating a manufacturing step of the electronic device shown in FIG. 1.

FIG. 15 is a partial enlarged sectional view illustrating a manufacturing step of the electronic device shown in FIG. 1.

FIG. 16 is a partial enlarged sectional view illustrating a manufacturing step of the electronic device shown in FIG. 1.

FIG. 17 is a sectional view illustrating a manufacturing step of the electronic device shown in FIG. 1.

FIG. 18 is a sectional view illustrating a manufacturing step of the electronic device shown in FIG. 1.

FIG. 19 is a sectional view illustrating a manufacturing step of the electronic device shown in FIG. 1.

FIG. 20 is a sectional view illustrating a manufacturing step of the electronic device shown in FIG. 1.

FIG. 21 is a sectional view illustrating a manufacturing step of the electronic device shown in FIG. 1.

FIG. 22 is a sectional view illustrating a manufacturing step of the electronic device shown in FIG. 1.

FIG. 23 is a sectional view illustrating a manufacturing step of the electronic device shown in FIG. 1.

FIG. 24 is a sectional view illustrating a manufacturing step of the electronic device shown in FIG. 1.

FIG. 25 is a plan view of an electronic device according to a second embodiment of the present disclosure.

FIG. 26 is a sectional view taken along line XXVI-XXVI in FIG. 25.

FIG. 27 is a sectional view taken along line XXVII-XXVII in FIG. 25.

FIG. 28 is a partial enlarged sectional view of FIG. 26.

FIG. 29 is a sectional view illustrating a manufacturing step of the electronic device shown in FIG. 25.

FIG. 30 is a sectional view illustrating a manufacturing step of the electronic device shown in FIG. 25.

FIG. 31 is a sectional view illustrating a manufacturing step of the electronic device shown in FIG. 25.

FIG. 32 is a sectional view illustrating a manufacturing step of the electronic device shown in FIG. 25.

FIG. 33 is a sectional view illustrating a manufacturing step of the electronic device shown in FIG. 25.

FIG. 34 is a plan view of an electronic device according to a third embodiment of the present disclosure.

FIG. 35 is a sectional view taken along line XXXV-XXXV in FIG. 34.

FIG. 36 is a sectional view of a variation of the third embodiment of the present disclosure.

### DETAILED DESCRIPTION OF EMBODIMENTS

Modes for carrying out the present disclosure are described below based on the accompanying drawings.

### First Embodiment

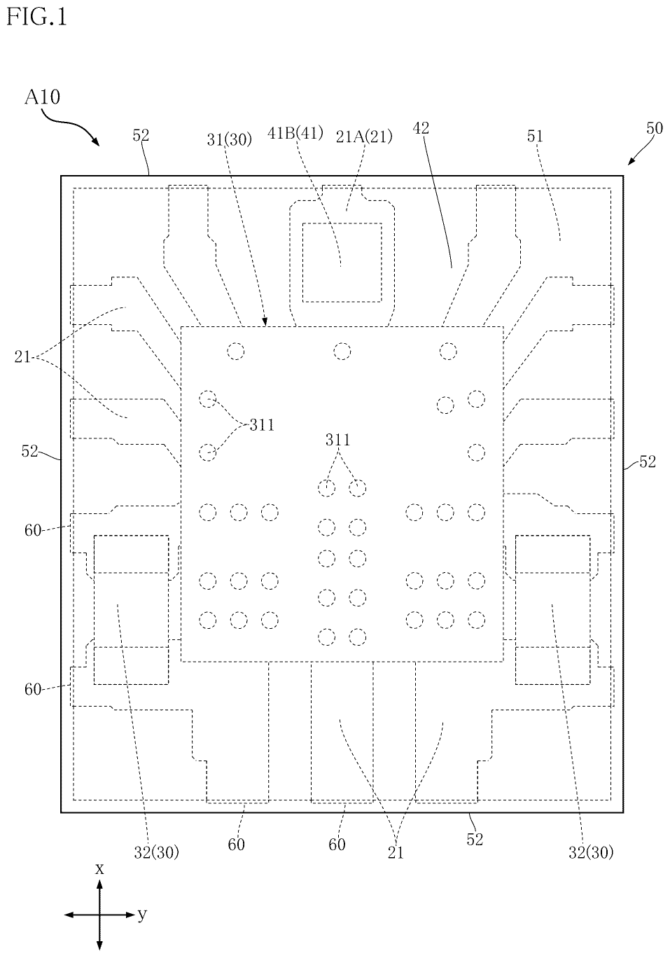

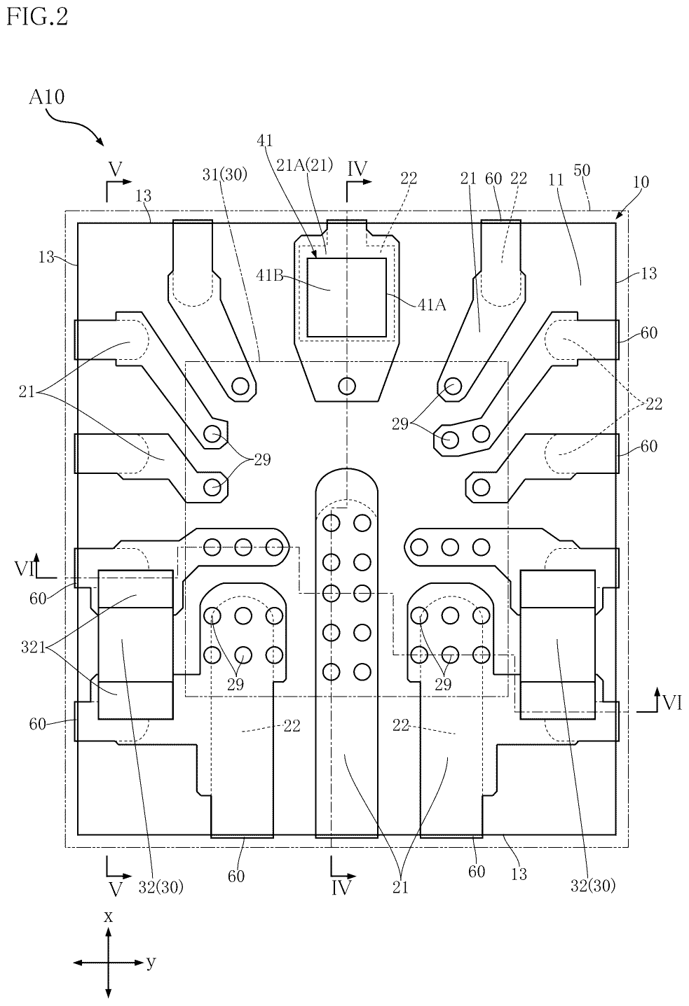

An electronic device A10 according to a first embodiment of the present disclosure will be described based on FIGS. 1 to 7. The electronic device A10 includes a substrate 10, a plurality of wiring layers 21, a plurality of terminals 22, conductive bonding layers 29, a plurality of electronic elements 30, a pillar 41, a shield 42, bonding layers 49, a sealing resin 50, and a plurality of covering layers 60. The electronic device A10 is of a resin package type for surface-mounting on a circuit board. The resin package type is the QFN (quad flat non-leaded package) in which leads do not protrude from the sealing resin 50. In FIG. 2, the semiconductor element 31, which will be described later, of the electronic elements 30 and the sealing resin 50 are transparent for convenience of understanding. In FIG. 2, the outlines of the semiconductor element 31 and the sealing resin 50 are indicated by imaginary lines (two-dot chain lines). Also, in FIG. 2, line IV-IV and line VI-VI are indicated by single-dot chain lines.

In the description of the electronic device A10, the direction that is normal to the mount surface 11, which will be described later, of the substrate 10 is referred to as the “first direction z”. A direction orthogonal to the first direction z is referred to as the “second direction x”. The direction orthogonal to the first direction z and the second direction x is referred to as the “third direction y”. As shown in FIG. 1, the electronic device A10 is rectangular as viewed in the first direction z.

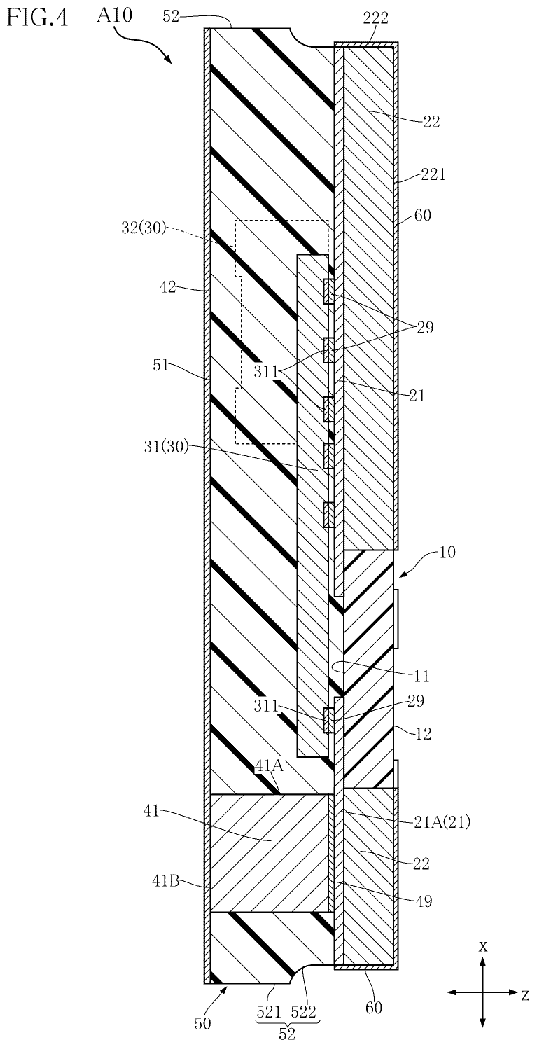

As shown in FIGS. 4 to 6, the substrate 10 supports the plurality of wiring layers 21 and the sealing resin 50. The substrate 10 has electrical insulation property. Examples of the material for the substrate 10 include a black epoxy resin. The substrate 10 has a mount surface 11, a reverse surface 12, and a plurality of end surfaces 13. The mount surface 11 and the reverse surface 12 face away from each other in the first direction z. The mount surface 11 faces the wiring layers 21. The reverse surface 12 is exposed to the outside. When the electronic device A10 is mounted on a circuit board, the reverse surface 12 faces the circuit board. The plurality of end surfaces 13 face in a direction orthogonal to the first direction z. The end surfaces 13 are connected to the mount surface 11 and the reverse surface 12. The plurality of end surfaces 13 include two end surfaces 13 facing in the second direction x and two end surfaces 13 facing in the third direction y.

As shown in FIGS. 4 to 6, the wiring layers 21 are disposed on the mount surface 11 of the substrate 10. The wiring layers 21, together with the terminals 22, form conductive paths between the electronic elements 30 and the circuit board on which the electronic device A10 is mounted. The wiring layers 21 contain copper (Cu).

As shown in FIGS. 4 to 6, at least a portion of each of the wiring layers 21 is housed in the substrate 10. Each of the terminals 22 is electrically connected to one of the wiring layers 21. The terminals 22 contain copper.

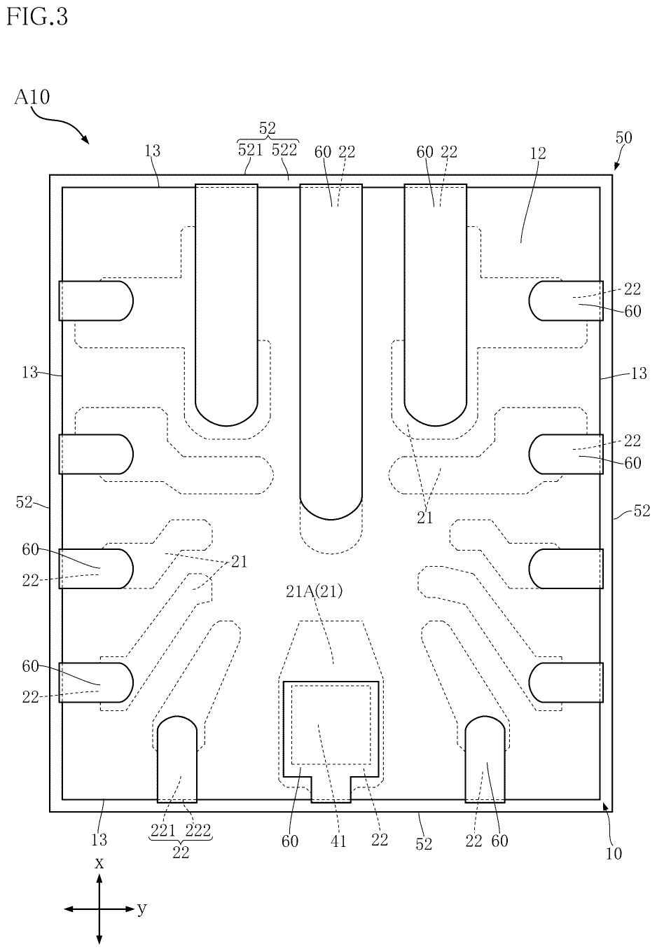

As shown in FIGS. 3 to 5, each of the terminals 22 has a first surface 221 and a second surface 222. The first surface 221 faces the same side as the reverse surface 12 of the substrate 10 in the first direction z. The first surface 221 is exposed from the reverse surface 12. The second surface 222 faces in a direction orthogonal to the first direction z. The second surface 222 is exposed from one of the end surfaces 13 of the substrate 10.

As shown in FIGS. 4 to 6, each of the electronic elements 30 is conductively bonded to at least one of the wiring layers 21. Thus, each of the electronic elements 30 is electrically connected to at least one of the wiring layers 21. The plurality of semiconductor elements 30 include a semiconductor element 31 and two passive elements 32.

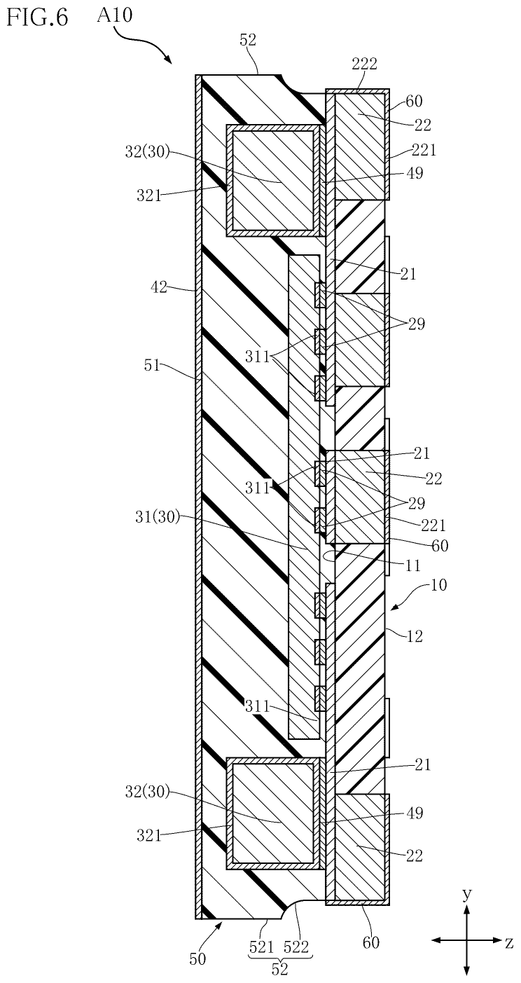

As shown in FIGS. 4 and 6, the semiconductor element 31 is conductively bonded to the wiring layers 21 via the conductive bonding layers 29. The semiconductor element 31 is, for example, an LSI (Large Scale Integration). The semiconductor element 31 has a plurality of electrodes 311.

As shown in FIGS. 4 and 6, the plurality of electrodes 311 are located on one side in the first direction z of the semiconductor element 31. Each electrode 311 faces one of the wiring layers 21. Each electrode 311 is conductively bonded to one of the wiring layers 21 via a conductive bonding layer 29. The conductive bonding layers 29 contain nickel (Ni), Tin (Sn), and silver (Ag). Alternatively, the conductive bonding layers 29 may contain nickel, tin, and antimony (Sb).

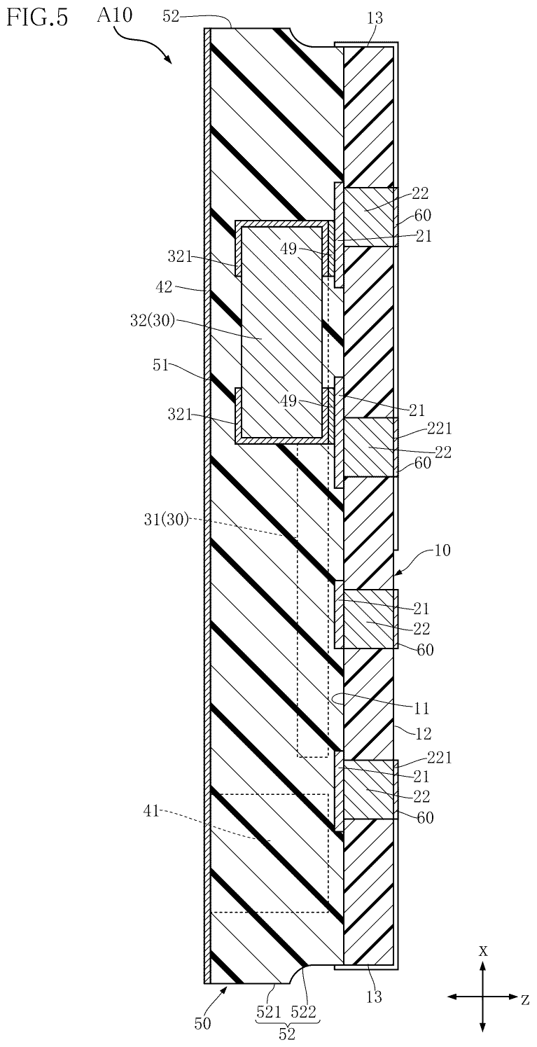

As shown in FIGS. 5 and 6, each of the two passive elements 32 is conductively bonded to two of the wiring layers 21. The two passive elements 32 are surface-mount electronic components, such as resistors, capacitors, and inductors. The dimension in the first direction z of each of the two passive elements 32 is greater than the dimension in the first direction z of the semiconductor element 31. Each of the two passive elements 32 has two electrodes 321. The two electrodes 321 are spaced apart from each other in a direction orthogonal to the first direction z. Each of the two electrodes 321 is conductively bonded to one of the wiring layers 21 via a bonding layer 49. The bonding layers 49 are, for example, solder.

As shown in FIGS. 4 to 6, the sealing resin 50 covers a portion of each of the wiring layers 21 and the electronic elements 30. The sealing resin 50 has electrical insulation property. Examples of the material for the sealing resin 50 include a black epoxy resin.

As shown in FIGS. 4 to 6, the sealing resin 50 has a top surface 51 and a plurality of side surfaces 52. The top surface 51 faces the same side as the mount surface 11 of the substrate 10 in the first direction z. The side surfaces 52 are connected to the top surface 51. Each of the side surfaces 52 faces one of the second direction x and the third direction y. As shown in FIG. 7, each of the side surfaces 52 includes a first region 521 and a second region 522. The first region 521 is connected to the top surface 51. The second region 522 is located opposite to the top surface 51 with respect to the first region 521 in the first direction z and connected to the first region 521. As viewed in the first direction z, the second region 522 overlaps with the top surface 51.

As shown in FIG. 4, the pillar 41 is conductively bonded to the ground wiring 21A, which is among the plurality of wiring layers 21, via a bonding layer 49. Thus, the pillar 41 is electrically connected to the ground wiring 21A. The ground wiring 21A corresponds to the ground (GND) of the electronic device A10. The pillar 41 extends in the first direction z. The dimension in the first direction z of the pillar 41 is greater than the dimension in the first direction z of each of the two passive elements 32.

As shown in FIG. 4, the pillar 41 has a peripheral surface 41A and a connection surface 41B. The peripheral surface 41A faces in a direction orthogonal to the first direction z. The peripheral surface 41A is covered with the sealing resin 50. The connection surface 41B faces the same side as the top surface 51 of the sealing resin 50 in the first direction z. The connection surface 41B is exposed from the top surface 51.

As shown in FIGS. 4 to 6, the shield 42 covers at least a portion of the top surface 51 of the sealing resin 50. In the electronic device A10, the shield 42 covers the entirety of the top surface 51. As viewed in the first direction z, the shield 42 overlaps with each of the electronic elements 30. The shield 42 is a thin metal film. The thin metal film contains, for example, copper.

As shown in FIG. 7, the connection surface 41B of the pillar 41 is in contact with the shield 42. Thus, the shield 42 is electrically connected to the pillar 41.

As shown in FIGS. 2 and 3, the covering layers 60 are exposed to the outside. As shown in FIGS. 3, 4, and 6, each of the covering layers 60 covers the first surface 221 and the second surface 222 of one of the terminals 22. As shown in FIG. 7, each covering layer 60 covers a portion of one of the wiring layers 21.

The plurality of covering layers 60 are electrical conductors. The electronic device A10 is mounted on a circuit board by conductively bonding the covering layers 60 to the circuit board via solder. Each covering layer 60 includes a plurality of metal layers. The metal layers are a nickel layer and a gold (Au) layer, which are laminated in this order on one of the terminals 22. Alternatively, the metal layers may be a nickel layer, a palladium (Pd) layer, and a gold layer, which are laminated in this order on one of the terminals 22. Therefore, each of the covering layers 60 contains gold.

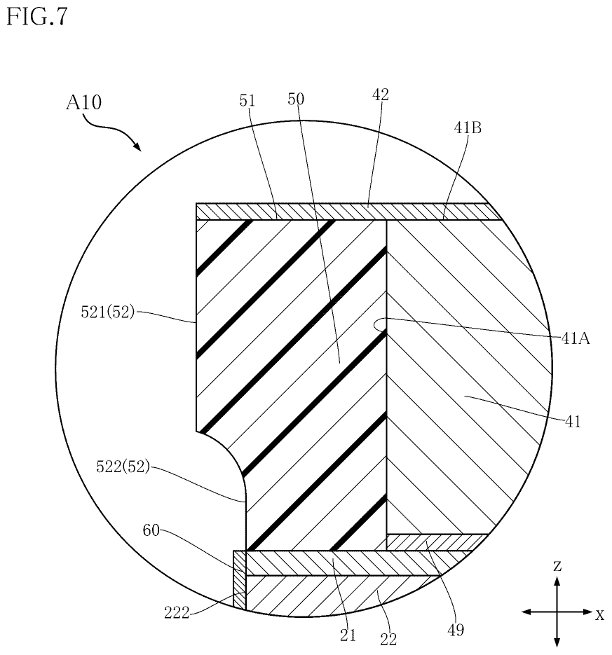

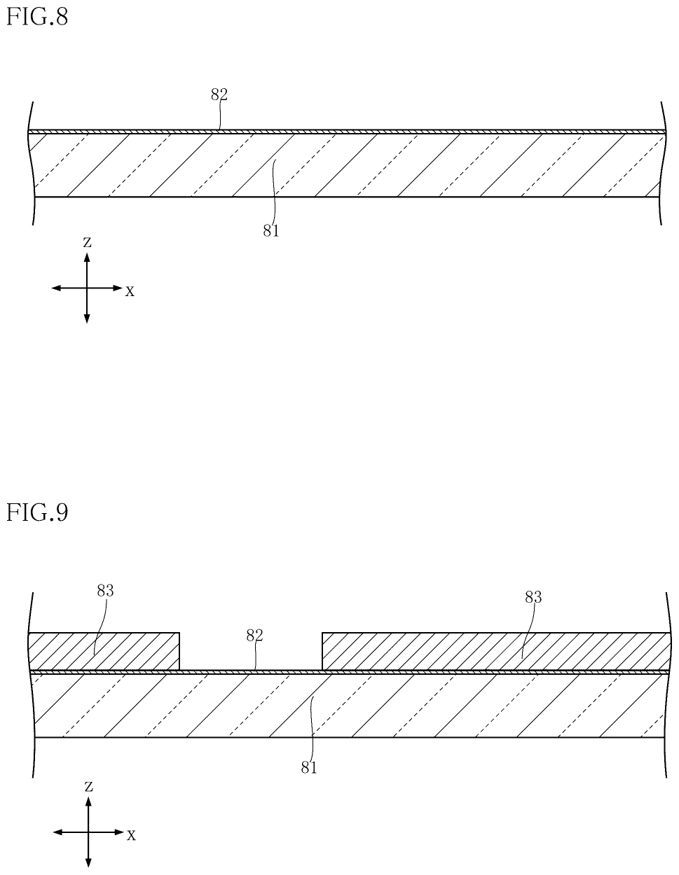

Next, an example of a method for manufacturing the electronic device A10 will be described based on FIGS. 8 to 24. Here, the cross-sectional positions of FIGS. 8 to 12 and FIGS. 17 to 24 are the same (or approximately the same) as the cross-sectional position of FIG. 4.

First, an intermediate layer 82 covering one side in the first direction z of a support member 81 is formed as shown in FIG. 8. The intermediate layer 82 is made up of a thin metal film that is in contact with the support member 81 and made of titanium, and another thin metal film laminated on the thin metal film and made of copper. The intermediate layer 82 is formed by depositing each metal film by sputtering.

Next, a plurality of first conductive layers 83 protruding in the first direction z from the intermediate layer 82 are formed as shown in FIG. 9. Portions of the first conductive layers 83 will become the terminals 22 of the electronic device A10. To form the first conductive layers 83, lithographic patterning is first performed on the intermediate layer 82. Next, a plurality of first conductive layers 83 are deposited by electrolytic plating using the intermediate layer 82 as the conductive path. Finally, the mask layer used for lithographic patterning is removed. In this way, the first conductive layers 83 are formed.

Next, a first resin layer 84 covering the first conductive layers 83 is formed as shown in FIG. 10. A portion of the first resin layer 84 will become the substrate 10 of the electronic device A10. The first resin layer 84 is made of a material including a black epoxy resin. The first resin layer 84 is formed by compression molding. In this step, the first resin layer 84 is formed to be in contact with the intermediate layer 82 and cover the entirety of the plurality of first conductive layers 83.

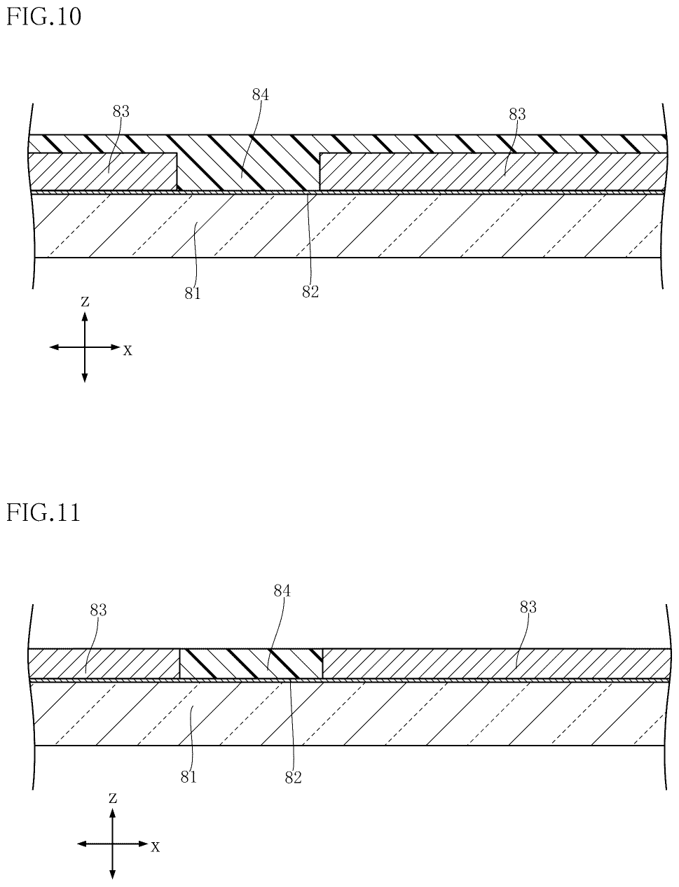

Next, a portion of each of the first conductive layers 83 and a portion of the first resin layer 84 are removed by grinding as shown in FIG. 11. The portions removed in this step are the portions located opposite to the side facing the intermediate layer 82 in the first direction z. As a result, the first conductive layers 83 are exposed from the surface of the first resin layer 84 that faces in the first direction z.

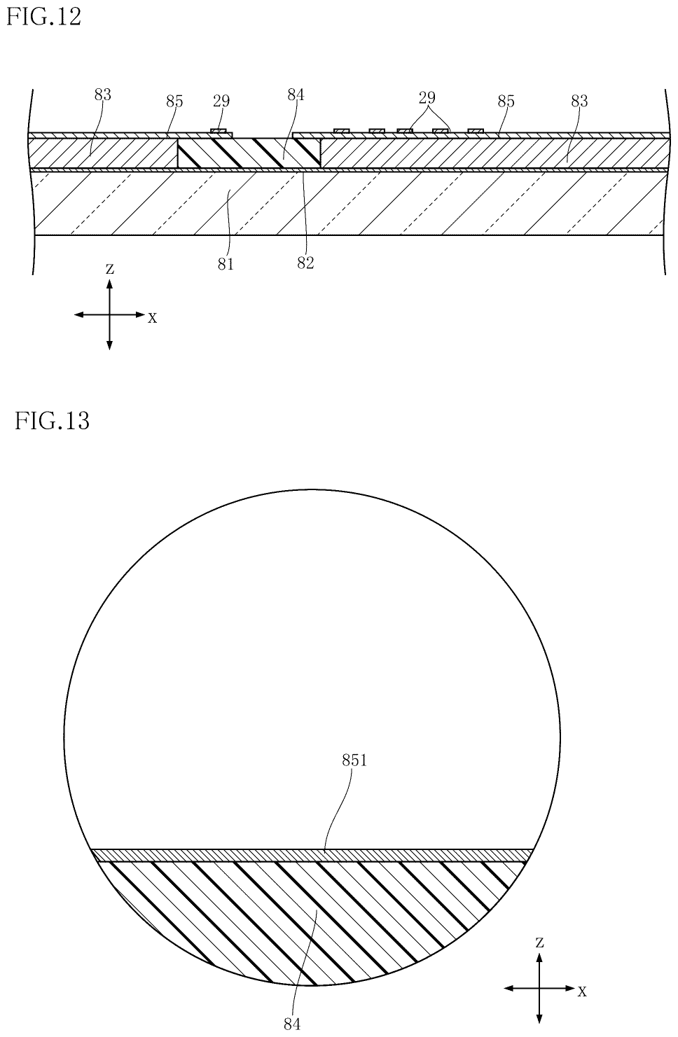

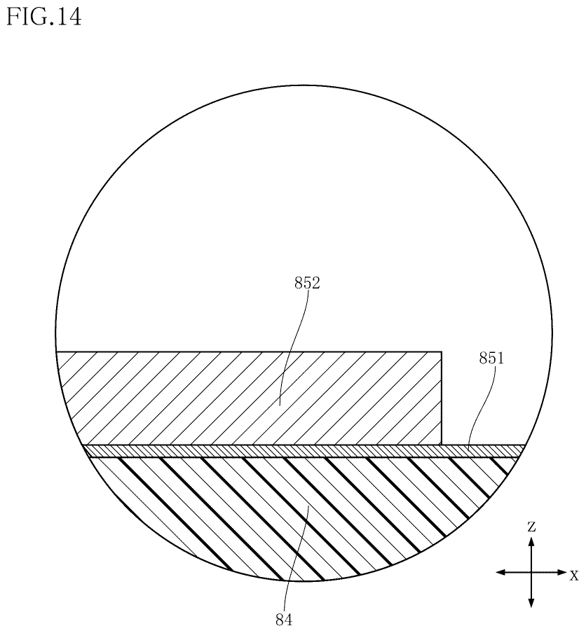

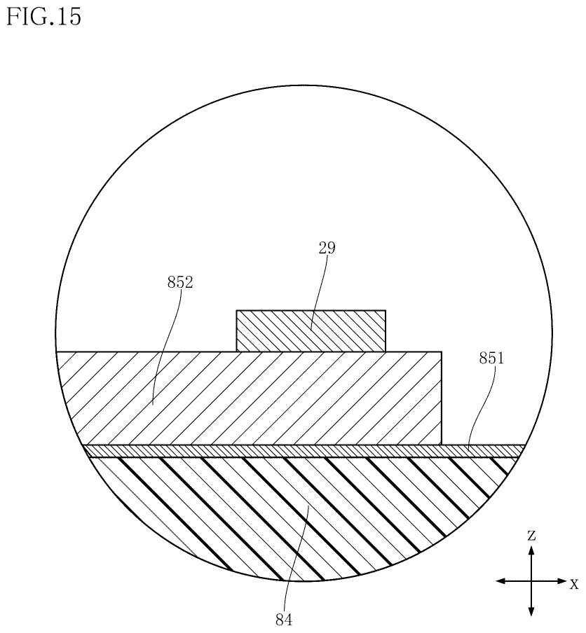

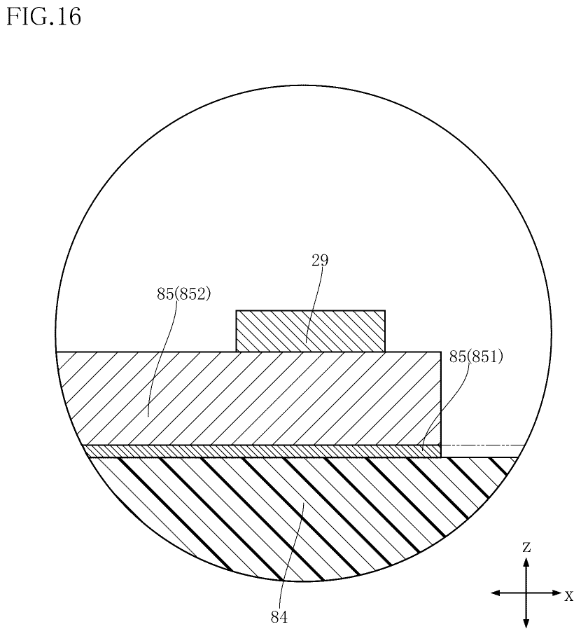

Next, as shown in FIG. 12, a plurality of second conductive layers 85 which are in contact with the surface of the first resin layer 84 that faces in the first direction z and each of which is connected to at least one of the first conductive layers 83, and conductive bonding layers 29 laminated on the second conductive layers 85 are formed. The second conductive layers 85 will become the wiring layers 21 of the electronic device A10. The process of forming the second conductive layers 85 and the conductive bonding layers 29 include the step of forming a base layer 851 shown in FIG. 13, the step of forming a main layer 852 shown in FIG. 14, the step of forming the conductive bonding layers 29 shown in FIG. 15, and the step of removing a portion of the base layer 851 shown in FIG. 16.

First, as shown in FIG. 13, a base layer 851 is formed that entirely covers portions of the first conductive layers 83 and the first resin layer 84 that are located on the side opposite to the side that faces the intermediate layer 82 (see FIG. 12) in the first direction z. The base layer 851 is made of the same thin metal film as the intermediate layer 82. Thus, the base layer 851 contains titanium and copper. The base layer 851 is formed by sputtering.

Next, a main layer 852 is formed as shown in FIG. 14. To form the main layer 852, lithographic patterning is first performed on the base layer 851. Next, the main layer 852 is deposited on the base layer 851 by electrolytic plating using the base layer 851 as the conductive path. The main layer 852 contains copper. Finally, the mask layer used for lithographic patterning is removed.

Next, as shown in FIG. 15, a conductive bonding layer 29 protruding from the main layer 852 in the first direction z is formed. To form the conductive bonding layer 29, lithographic patterning is first performed on the base layer 851 and the main layer 852. Next, the conductive bonding layer 29 is deposited on the main layer 852 by electrolytic plating using the base layer 851 and the main layer 852 as the conductive path. The conductive bonding layer 29 includes a nickel layer, and an alloy layer laminated ton the nickel layer and containing tin. Finally, the mask layer used for lithographic patterning is removed.

Finally, as shown in FIG. 16, the base layer 851 exposed to the outside from the main layer 852 is removed. Removal of the base layer 851 is performed by wet etching using a mixed solution of sulfuric acid (H₂SO₄) and hydrogen peroxide (H₂O₂). In this way, the second conductive layers 85 and the conductive bonding layers 29 are obtained. In the following description of the method for manufacturing the electronic device A10, the second conductive layers 85 are regarded as the wiring layers 21.

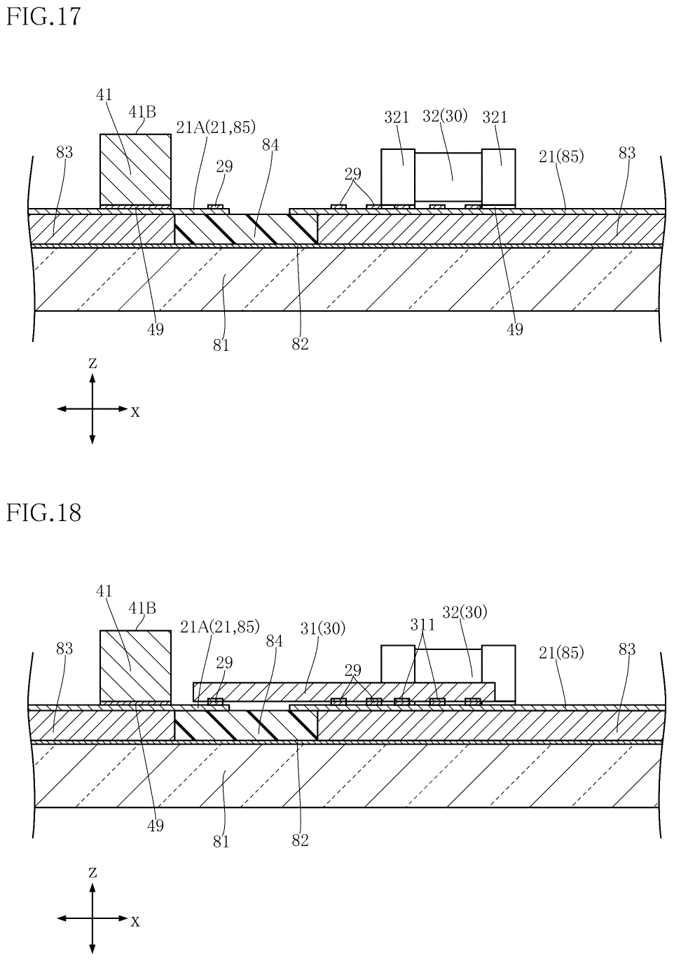

Next, as shown in FIG. 17, the two electrodes 321 of each of the two passive elements 32 and the pillar 41 are conductively bonded to some of the wiring layers 21. The conductive bonding of the two passive element 32 and the pillar 41 is performed by melting and solidifying the bonding layer 49 by reflowing.

Next, as shown in FIG. 18, the electrodes 311 of the semiconductor element 31 are conductively bonded to some of the wiring layers 21. The conductive bonding is performed by flip chip bonding. The conductive bonding of the semiconductor element 31 is performed by temporarily attaching each of the electrodes 311 to the conductive bonding layers 29 and then melting and solidifying the conductive bonding layers 29 by reflowing.

Next, as shown in FIG. 19, a second resin layer 86 covering the wiring layers 21 and the electronic elements 30 is formed. A portion of the second resin layer 86 will become the sealing resin 50 of the electronic device A10. The second resin layer 86 is made of a material including a black epoxy resin. The second resin layer 86 is formed by compression molding. This step is performed such that the entire pillar 41 is covered with the sealing resin 50.

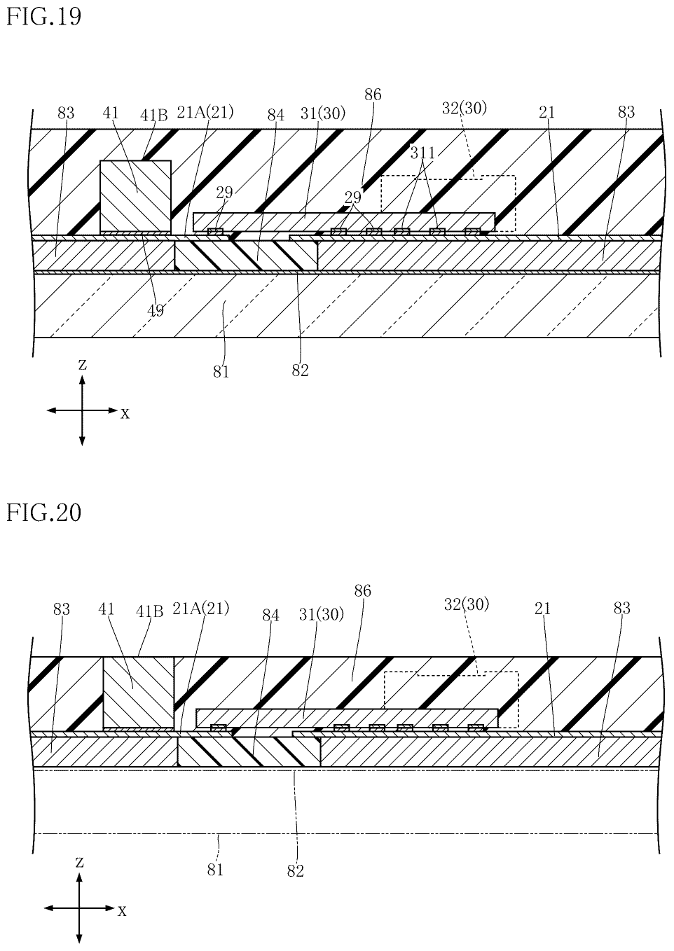

Next, as shown in FIG. 20, the support member 81 and the intermediate layer 82 are removed by grinding. In this step, a portion of each of the first conductive layers 83 and a portion of the first resin layer 84 are removed by grinding. Also, a portion of the second resin layer 86 that is located on the above-described one side in the first direction z is removed by grinding. This step is performed such that the connection surface 41B of the pillar 41 is exposed from the second resin layer 86.

Next, as shown in FIG. 21, a shield 42 covering the above-described one side in the first direction z of the second resin layer 86 is formed. The shield 42 is formed by depositing a thin metal film by sputtering. The thin metal film can be formed by electroless plating. Alternatively, the shield 42 can be formed by adhering metal particles to the surface of the second resin layer 86 by spray coating or printing.

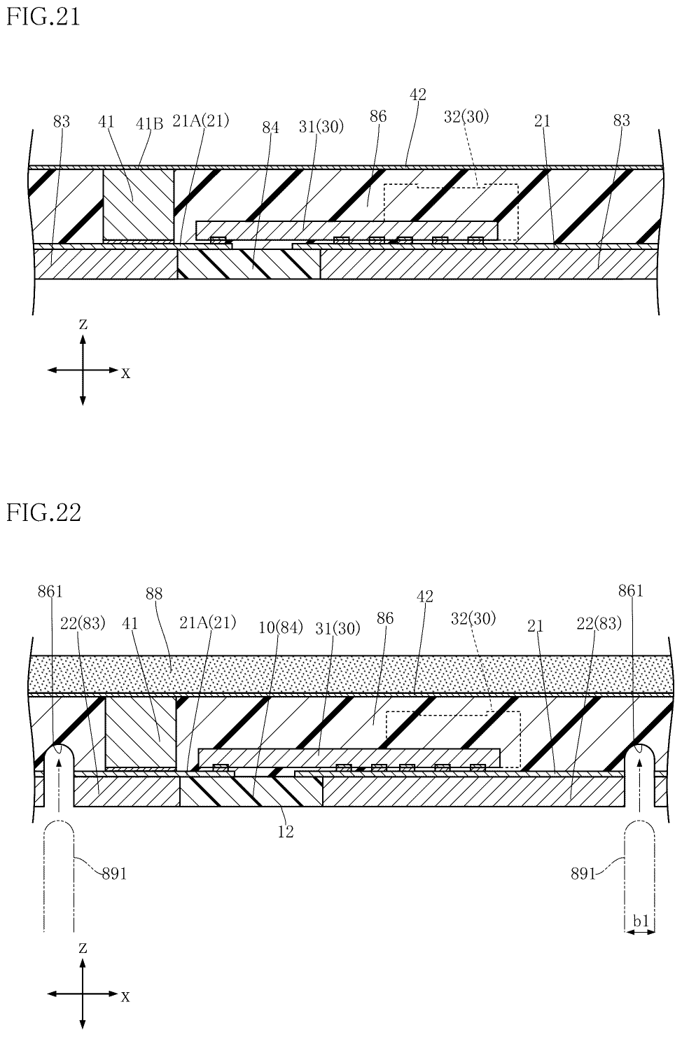

Next, as shown in FIG. 22, a tape 88 is attached to the surface of the shield 42. The tape 88 is a dicing tape. Next, a plurality of grooves 861 recessed in the first direction z are formed by removing a portion of each of the first conductive layers 83, a portion of the first resin layer 84, a portion of each of the wiring layers 21, and a portion of the second resin layer 86 by using a first blade 891 having a width b1. The plurality of grooves 861 are formed in a grid extending along each of the second direction x and the third direction y.

Next, the surfaces of the first conductive layers 83 that are exposed to the outside form the first resin layer 84 are smoothed by wet etching. By this step, the first conductive layers 83 become the terminals 22 of the electronic device A10. Also, the first resin layer 84 becomes the substrate 10 of the electronic device A10. The surface of the substrate 10 that faces in the first direction z and is exposed to the outside corresponds to the reverse surface 12 of the substrate 10.

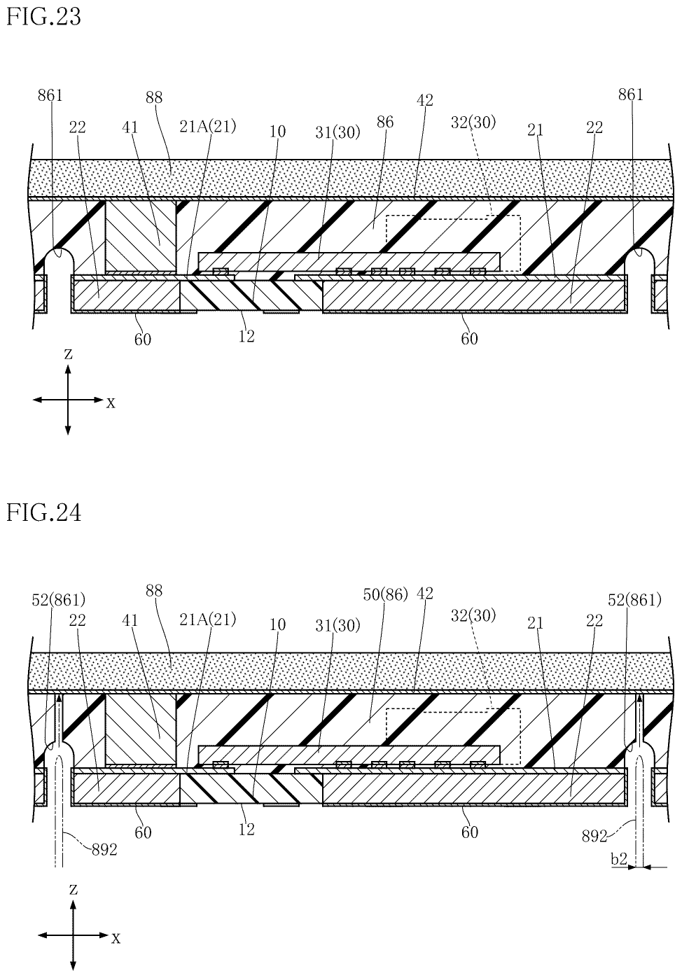

Next, as shown in FIG. 23, a plurality of covering layers 60 individually covering the surfaces of the terminals 22 that are exposed to the outside from the substrate 10 are formed. The covering layers 60 are formed by electroless plating.

Finally, as shown in FIG. 24, the second resin layer 86 is cut by using a second blade 892 having a width b2. The width b2 is smaller than the width b1 of the first blade 891. In cutting the second resin layer 86, the second blade 892 is passed through each of the grooves 861 and then moved in the first direction z until the second blade 892 comes into contact with the tape 88. By this step, the second resin layer 86 becomes the sealing resin 50 of the electronic device A10. Through the above process, the electronic device A10 is obtained.

Next, the effect of the electronic device A10 will be described.

The electronic device A10 includes wiring layers 21, electronic elements 30 conductively bonded to wiring layers 21, and the sealing resin 50 covering the electronic elements 30. The sealing resin 50 has the top surface 51 facing in the first direction z. The electronic device A10 further includes a pillar 41 electrically connected to a wiring layer 21, and a shield 42 electrically connected to the pillar 41. The pillar 41 has the peripheral surface 41A covered with the sealing resin 50, and the connection surface 41B facing the same side as the top surface 51 in the first direction z. The connection surface 41B is in contact with the shield 42. With such a configuration, the shield 42 reduces both the noise generated from the electronic elements 30 and the noise entering the electronic device A10 from the outside. This is because the shield 42 blocks most of the electromagnetic waves. The electromagnetic waves blocked by the shield 42 generate an electromotive force in the shield 42. The current thus generated flows to the outside of the electronic device A10 through the pillar 41 and the ground wiring 21A of the wiring layers 21. In addition, the dimension in the first direction z of the shield 42 is smaller than the dimension in the first direction z of the metal housing. With such a configuration of the electronic device A10, it is possible to reduce noise while reducing the size of the electronic device A10.

As viewed in the first direction z, the shield 42 overlaps with the electronic elements 30. Such a configuration efficiently reduces both the noise generated from the electronic elements 30 and the noise entering the electronic device A10 from the outside.

The shield 42 covers the entirety of the top surface 51 of the sealing resin 50. With such a configuration, the shield 42 has an increased surface area, which improves the noise reducing effect of the electronic device A20.

The electronic device A10 further includes a bonding layer 49 that conductively bonds a wiring layer 21 and the pillar 41. With such a configuration, a pillar 41 obtained from a metal piece can be disposed in the electronic device A10 even if the dimension in the first direction z of the electronic element 30 is relatively large. Therefore, it is not necessary to form the pillar 41 by electrolytic plating.

The electronic device A10 further includes the substrate 10 supporting the wiring layers 21 and the sealing resin 50, and the terminals 22 electrically connected to the wiring layers 21. At least portions of the terminals 22 are housed in the substrate 10. The first surfaces 221 of the terminals 22 that face in the first direction z are exposed from the substrate 10. In this case, the electronic device A10 further includes the covering layers 60 covering the first surfaces 221. The covering layers 60 are electrical conductors containing gold. Such a configuration provides good wettability of molten solder to the covering layers 60 when the electronic device A10 is mounted on a circuit board. Thus, reduction of the bond area of the covering layers 60 to the solder is prevented.

In the above case, the second surfaces 222 of the terminals 22 that face in a direction orthogonal to the first direction z are exposed from the substrate 10. The covering layers 60 cover the second surfaces 222. With such a configuration, when the electronic device A10 is mounted on a circuit board, the molten solder easily creeps up the covering layers 60 in the first direction z. This facilitates the formation of solder fillet. As a result, the bonding strength of the electronic device A10 to the circuit board is improved. Furthermore, after the electronic device A10 is mounted on a circuit board, the solder fillet is exposed to the outside, so that the mounting state of the electronic device A10 on the circuit board can be easily checked by visually inspecting the appearance.

### Second Embodiment

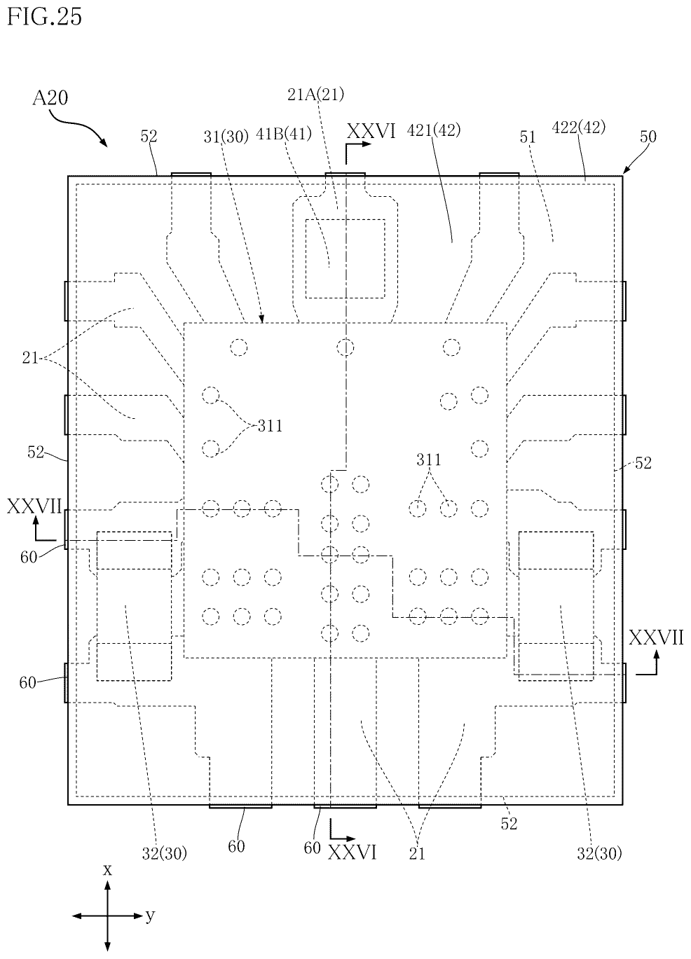

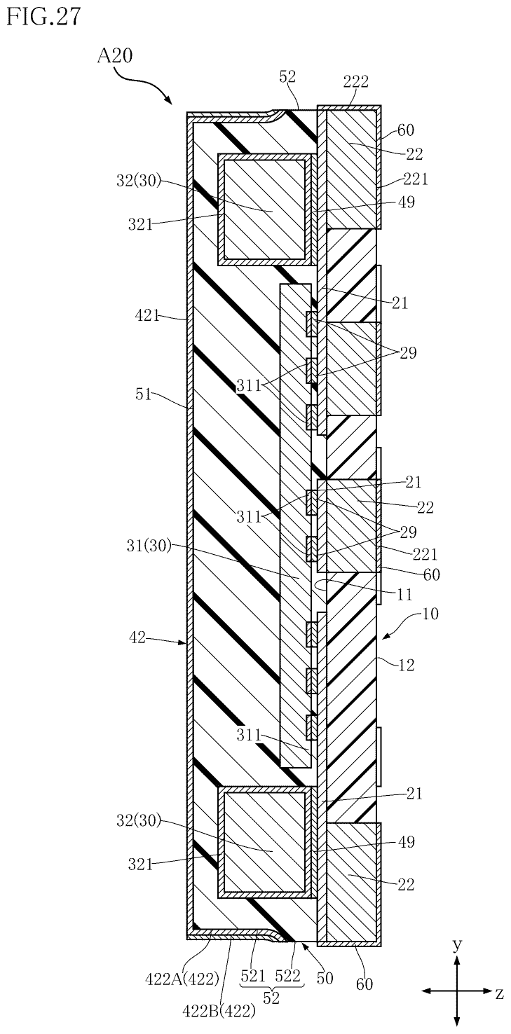

An electronic device A20 according to a second embodiment of the present disclosure will be described based on FIGS. 25 to 28. In these figures, the elements that are identical or similar to those of the electronic device A10 described above are denoted by the same reference signs, and the descriptions thereof are omitted.

The electronic device A20 differs from the electronic device A10 in the configurations of the shield 42 and the sealing resin 50.

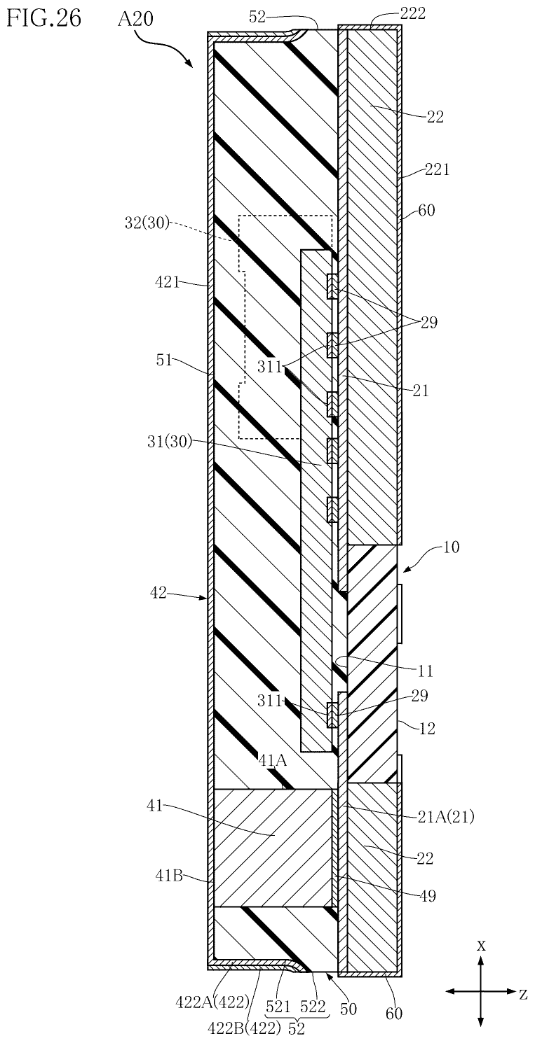

As shown in FIGS. 26 to 28, in each of the side surfaces 52 of the sealing resin 50, the first region 521 is located between the top surface 51 and the second region 522 in either the second direction x or the third direction y. As viewed in the first direction z, the first region 521 overlaps with the mount surface 11 of the substrate 10.

As shown in FIGS. 25 to 27, the shield 42 includes a top portion 421 and a side portion 422. The top portion 421 covers the top surface 51 of the sealing resin 50. The side portion 422 is connected to the top portion 421. The side portion 422 covers a portion of each of the side surfaces 52 of the sealing resin 50. The side portion 422 is spaced apart from the terminals 22 and the covering layers 60.

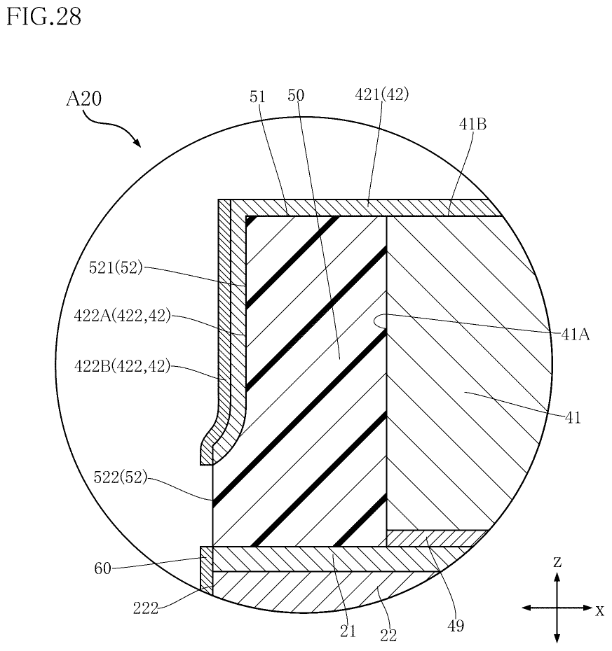

As shown in FIG. 28, the first region 521 of each of the side surfaces 52 of the sealing resin 50 is covered with the side portion 422. The second region 522 of each of the side surfaces 52 is exposed to the outside.

As shown in FIG. 28, the side portion 422 includes a first layer 422A and a second layer 422B. The first layer 422A is laminated on the first region 521 of each of the side surfaces 52 of the sealing resin 50. The second layer 422B is laminated on the first layer 422A. The second layer 422B contains the same metal as that contained in the covering layers 60.

Next, an example of a method for manufacturing the electronic device A20 will be described based on FIGS. 29 to 33. Here, the cross-sectional positions of FIGS. 29 to 33 are the same (or approximately the same) as the cross-sectional position of FIG. 26.

The steps shown in FIGS. 8 to 19 for manufacturing the electronic device A10 are the same for the example of the manufacturing method of the electronic device A20. Therefore, in the description of the example of the manufacturing method of the electronic device A20, the steps shown in FIGS. 8 to 19 are omitted, and the steps subsequent to the step shown in FIG. 19 are described.

After the step shown in FIG. 19 is completed, as shown in FIG. 29, a portion of the second resin layer 86 that is located on one side in the first direction z is removed by grinding. This step is performed such that the connection surface 41B of the pillar 41 is exposed from the second resin layer 86. Thereafter, a plurality of grooves 861 recessed in the first direction z are formed by removing a portion of the second resin layer 86 by using a first blade 891 having a width b1. The plurality of grooves 861 are formed in a grid extending along each of the second direction x and the third direction y.

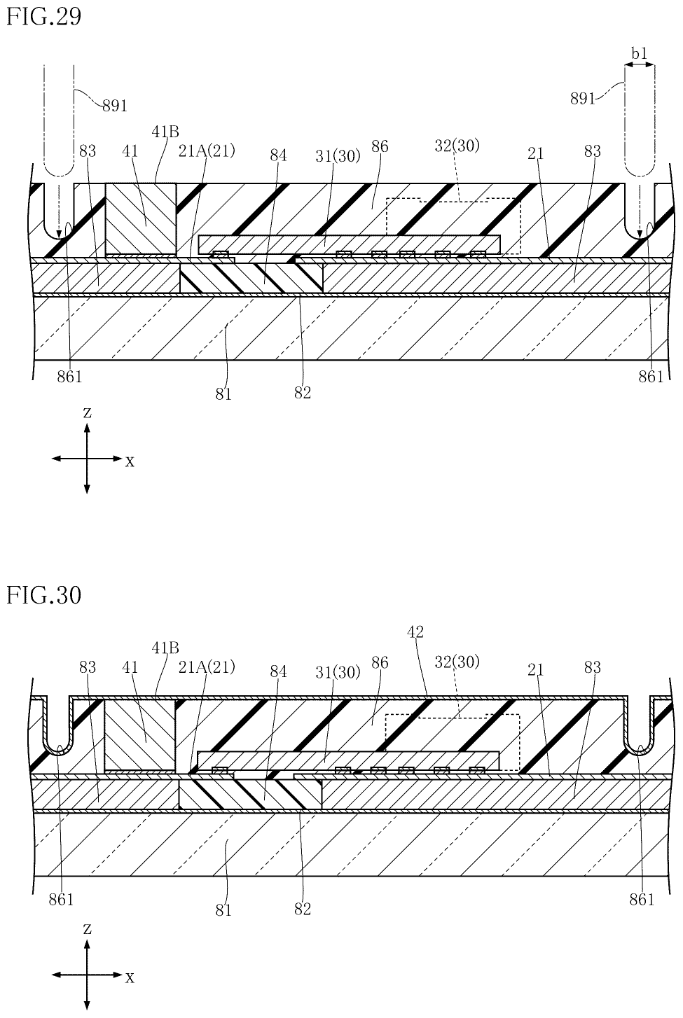

Next, as shown in FIG. 30, a shield 42 covering the above-described one side in the first direction z of the second resin layer 86 is formed. The method of forming the shield 42 is the same as that in the above-described example of the manufacturing method of the electronic device A10. This step is performed such that the shield 42 covers not only the surface of the second resin layer 86 that faces in the first direction z but also the surfaces of the second resin layer 86 that define the grooves 861.

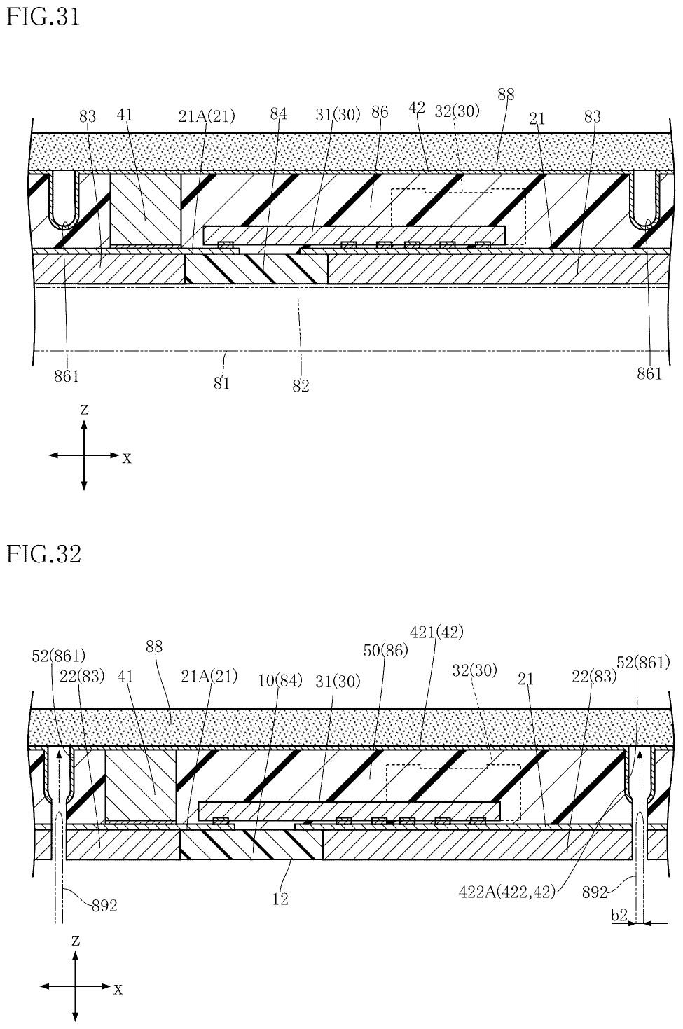

Next, as shown in FIG. 31, the support member 81 and the intermediate layer 82 are removed by grinding. In this step, a portion of each of the first conductive layers 83 and a portion of the first resin layer 84 are removed by grinding. Next, a tape 88 is attached to the surface of the shield 42.

Next, as shown in FIG. 32, each of the first conductive layers 83, the first resin layer 84, each of the wiring layers 21, and the second resin layer 86 are cut by using a second blade 892 having a width b2. In cutting these, the second blade 892 is passed through each of the grooves 861 and then moved in the first direction z until the second blade 892 comes into contact with the tape 88. By this step, the second resin layer 86 becomes the sealing resin 50 of the electronic device A20. Also, by this step, the top portion 421 of the shield 42 and the first layer 422A of the side portion 422 of the shield 42 are obtained.

Next, the surfaces of the first conductive layers 83 that are exposed to the outside form the first resin layer 84 are smoothed by wet etching. By this step, the first conductive layers 83 become the terminals 22 of the electronic device A20. Also, the first resin layer 84 becomes the substrate 10 of the electronic device A20. The surface of the substrate 10 that faces in the first direction z and is exposed to the outside corresponds to the reverse surface 12 of the substrate 10.

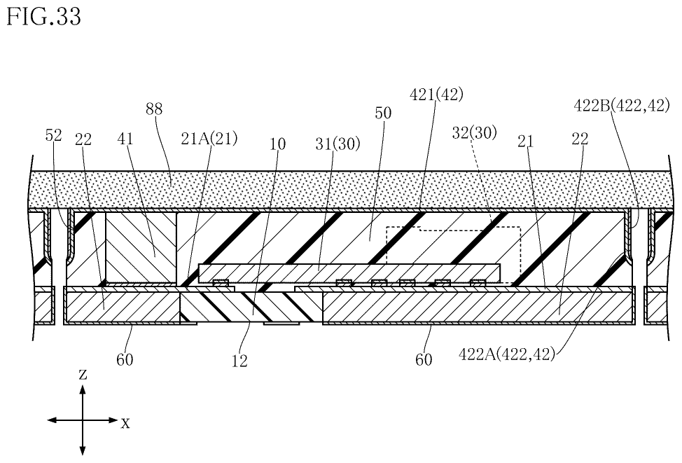

Finally, as shown in FIG. 33, a plurality of covering layers 60 individually covering the surfaces of the terminals 22 that are exposed to the outside from the substrate 10 are formed. The covering layers 60 are formed by electroless plating. Also, the second layer 422B of the side portion 422 of the shield 42 is formed by electroless plating at the same time (or almost at the same time) as the covering layers 60 are formed. Through the above process, the electronic device A20 is obtained.

Next, the effect of the electronic device A20 will be described.

The electronic device A20 includes wiring layers 21, electronic elements 30 conductively bonded to wiring layers 21, and the sealing resin 50 covering the electronic elements 30. The sealing resin 50 has the top surface 51 facing in the first direction z. The electronic device A20 further includes a pillar 41 electrically connected to a wiring layer 21, and a shield 42 electrically connected to the pillar 41. The pillar 41 has the peripheral surface 41A covered with the sealing resin 50, and the connection surface 41B facing the same side as the top surface 51 in the first direction z. The connection surface 41B is in contact with the shield 42. With such a configuration of the electronic device A20, it is possible to reduce noise while reducing the size of the electronic device A20. The electronic device A20 has a configuration in common with the electronic device A10, thereby achieving the same effect as the electronic device A10.

In the electronic device A20, the shield 42 has the top portion 421 covering the top surface 51 of the sealing resin 50, and the side portion 422 connected to the top portion 421 and covering portions of the side surfaces 52 of the sealing resin 50. With such a configuration, the shield 42 has a further increased surface area, which improves the noise reducing effect of the electronic device A20.

The side portion 422 of the shield 42 is spaced apart from the terminals 22 and the covering layers 60. This configuration prevents a short circuit caused by the shield 42 in the electronic device A20.

Each side surface 52 of the sealing resin 50 includes the first region 521 and the second region 522. The first region 521 is located between the top surface 51 and the second region 522 in the second direction x. The first region 521 is covered with the side portion 422 of the shield 42. The second region 522 is exposed to the outside. By adopting this configuration, the covering layers 60 covering the second surfaces 222 of the terminals 22 can be formed in the manufacturing steps of the electronic device A20 shown in FIGS. 29 to 33. This facilitates the formation of solder fillet when mounting the electronic device A20 on a circuit board.

The side portion 422 of the shield 42 includes the first layer 422A laminated on the first regions 521 of the side surfaces 52 of the sealing resin 50, and the second layer 422B laminated on the first layer 422A. The second layer 422B contains the same metal as that contained in the covering layers 60. The present configuration serves as an indicator that the second surfaces 222 of the terminals 22 have been reliably covered with the covering layer 60 in the step shown in FIG. 33 of the method for manufacturing the electronic device A20.

### Third Embodiment

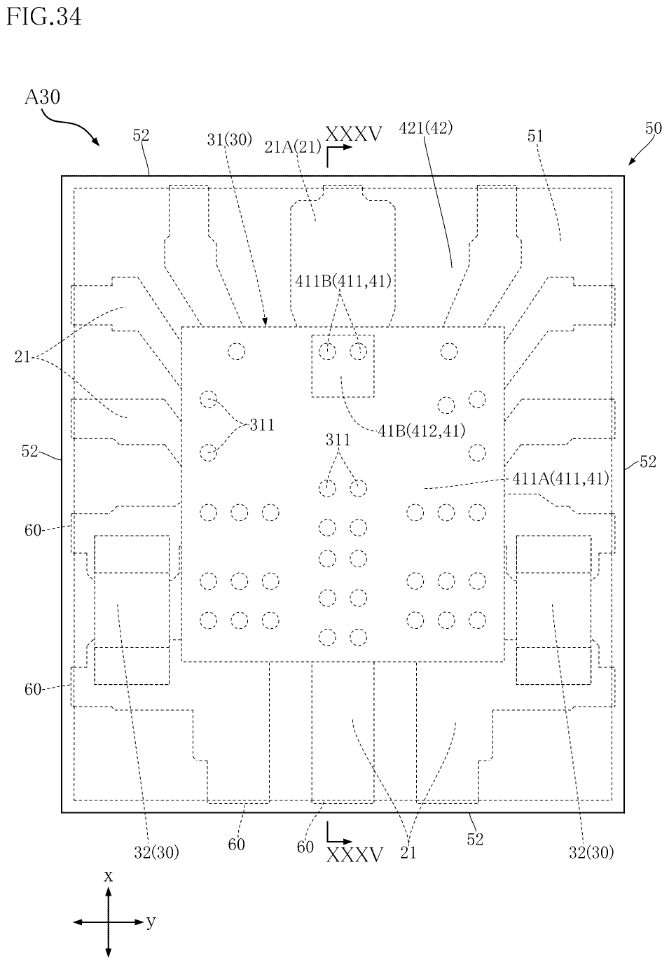

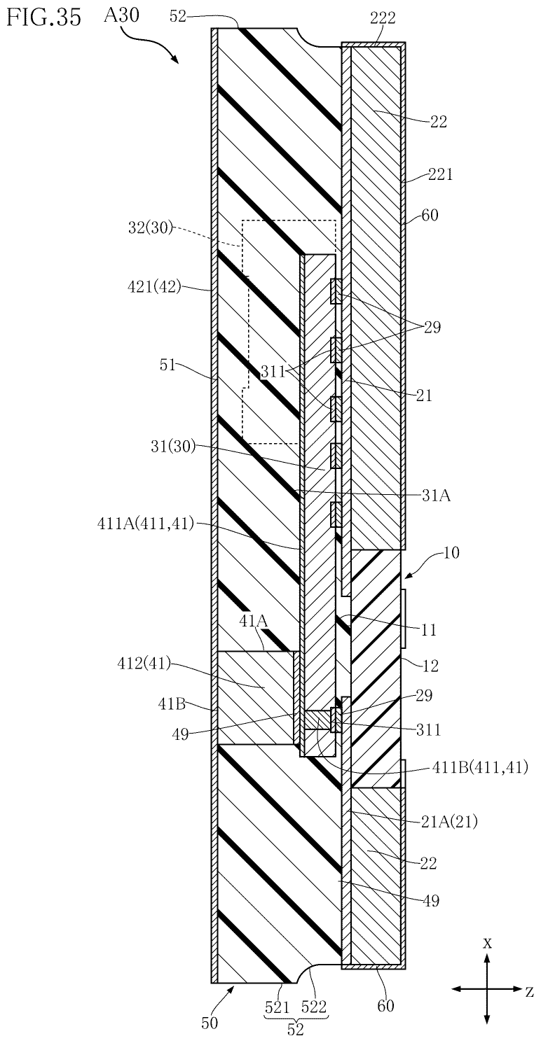

An electronic device A30 according to a third embodiment of the present disclosure will be described based on FIGS. 34 and 35. In these figures, the elements that are identical or similar to those of the electronic device A10 described above are denoted by the same reference signs, and the descriptions thereof are omitted.

The electronic device A30 differs from the electronic device A10 in the configuration of the pillar 41.

As shown in FIGS. 34 and 35, the pillar 41 includes a portion of one of the electronic elements 30. In the electronic device A30, the pillar 41 includes a portion of the semiconductor element 31. The pillar 41 has a first pillar 411 included in a portion of the semiconductor element 31, and a second pillar 412 electrically connected to the first pillar 411. The second pillar 412 includes a peripheral surface 41A and a connection surface 41B.

As shown in FIG. 35, the first pillar 411 has an outer portion 411A and an inner portion 411B. The outer portion 411A covers the upper surface 31A of the semiconductor element 31. The upper surface 31A faces the same side as the top surface 51 of the sealing resin 50 in the first direction z. The outer portion 411A is covered with the sealing resin 50. The inner portion 411B is located inside the semiconductor element 31. The inner portion 411B electrically connects the outer portion 411A and one of the electrodes 311 that is conductively bonded to the ground wiring 21A. Thus, the first pillar 411 is electrically connected to the one of the electrodes 311 and the ground wiring 21A. In the semiconductor element 31, an insulating layer, such as silicon nitride (Si₃N₄), is interposed between the first pillar 411 and the semiconductor layer.

As shown in FIG. 35, the second pillar 412 is conductively bonded to the outer portion 411A of the first pillar 411 via the bonding layer 49. The second pillar 412 is located between the upper surface 31A of the semiconductor element 31 and the top surface 51 of the sealing resin 50 in the first direction z. The dimension in the first direction z of the second pillar 412 is smaller than the dimension in the first direction z of the pillar 41 of the electronic device A10.

### Variation of the Third Embodiment

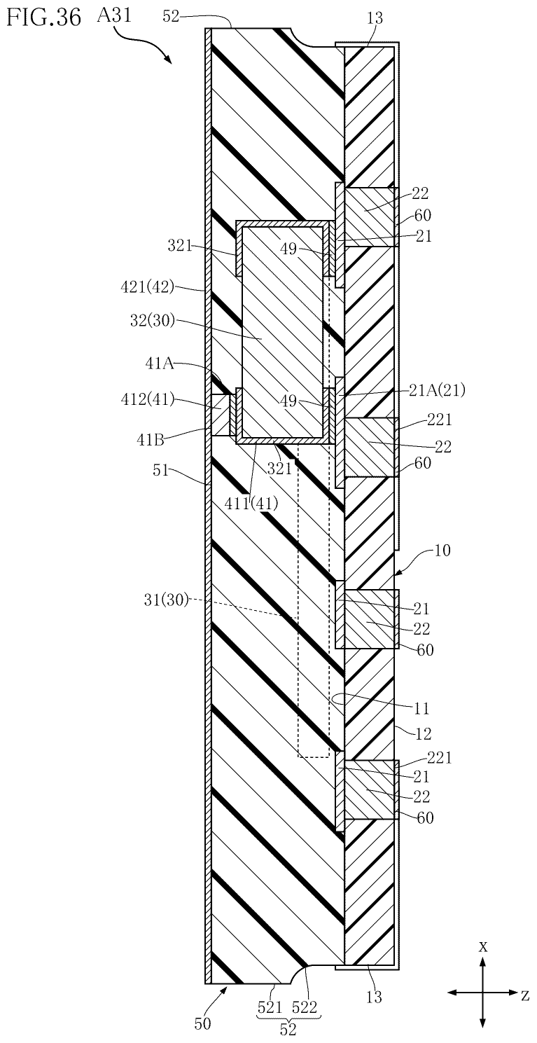

Next, an electronic device A31 as a variation of the electronic device A30 will be described based on FIG. 36. The cross-sectional position of FIG. 36 is the same (or approximately the same) as the cross-sectional position of FIG. 5 that shows the electronic device A10.

As shown in FIG. 36, in the electronic device A31, the pillar 41 includes a portion of one of the two passive elements 32. The pillar 41 has a first pillar 411 included in a portion of one of the passive elements 32, and a second pillar 412 electrically connected to the first pillar 411. The first pillar 411 is the electrode 321 of the one of the two passive elements 32. Thus, the electrode 321 including the first pillar 411 needs to be conductively bonded to the ground wiring 21A. Next, the effect of the electronic device A30 will be described.

The electronic device A30 includes wiring layers 21, electronic elements 30 conductively bonded to wiring layers 21, and the sealing resin 50 covering the electronic elements 30. The sealing resin 50 has the top surface 51 facing in the first direction z. The electronic device A30 further includes a pillar 41 electrically connected to a wiring layer 21, and a shield 42 electrically connected to the pillar 41. The pillar 41 has the peripheral surface 41A covered with the sealing resin 50, and the connection surface 41B facing the same side as the top surface 51 in the first direction z. The connection surface 41B is in contact with the shield 42. With such a configuration of the electronic device A30, it is possible to reduce noise while reducing the size of the electronic device A30. The electronic device A30 has a configuration in common with the electronic device A10, thereby achieving the same effect as the electronic device A10.

The present disclosure is not limited to the above-described embodiments. Various modifications in design may be made freely in the specific structure of each part of the present disclosure.

The present disclosure includes embodiments described in the following clauses.

Clause 1.

An electronic device comprising:

a wiring layer;

an electronic element conductively bonded to the wiring layer;

a sealing resin covering the electronic element;

a pillar extending in a first direction and electrically connected to the wiring layer; and

a shield electrically connected to the pillar, wherein

the sealing resin includes a top surface facing in the first direction and located opposite to the wiring layer with respect to the electronic element in the first direction,

the shield covers at least a portion of the top surface,

the pillar includes a peripheral surface facing in a direction orthogonal to the first direction and a connection surface facing a same side as the top surface in the first direction,

the peripheral surface is covered with the sealing resin, and

the connection surface is in contact with the shield.

Clause 2.

The electronic device according to clause 1, wherein the shield overlaps with the electronic element as viewed in the first direction.

Clause 3.

The electronic device according to clause 2, wherein the shield covers an entirety of the top surface.

Clause 4.

The electronic device according to clause 3, wherein the electronic element includes a semiconductor element,

the semiconductor element includes plurality of electrodes facing the wiring layer, and

the plurality of electrodes are conductively bonded to the wiring layer.

Clause 5.

The electronic device according to clause 4, wherein the electronic element includes a passive element, and

a dimension in the first direction of the passive element is greater than a dimension in the first direction of the semiconductor element.

Clause 6.

The electronic device according to clause 5, further comprising a bonding layer conductively bonding the wiring layer and the pillar.

Clause 7.

The electronic device according to clause 4, wherein the pillar includes a portion of the electronic element.

Clause 8.

The electronic device according to clause 7, wherein the pillar includes a first pillar included in a portion of the semiconductor element, and a second pillar including the connection surface and the peripheral surface and electrically connected to the first pillar, and

the first pillar is electrically connected to one of the plurality of electrodes.

Clause 9.

The electronic device according to any one of clauses 4 to 8, further comprising a substrate supporting the wiring layer and the sealing resin.

Clause 10.

The electronic device according to clause 9, further comprising a terminal electrically connected to the wiring layer, wherein

at least a portion of the terminal is housed in the substrate,

the terminal includes a first surface facing a side opposite to a side that faces the wiring layer in the first direction, and

the first surface is exposed from the substrate.

Clause 11.

The electronic device according to clause 10, further comprising a covering layer that covers the first surface,

wherein the covering layer is an electrical conductor containing gold.

Clause 12.

The electronic device according to clause 11, wherein the sealing resin includes a side surface facing in a second direction orthogonal to the first direction, and

the shield includes a top portion covering the top surface and a side portion connected to the top portion and covering a portion of the side surface.

Clause 13.

The electronic device according to clause 12, wherein the side portion is spaced apart from the terminal.

Clause 14.

The electronic device according to clause 13, wherein the side surface includes a first region connected to the top surface and a second region located opposite to the top surface with respect to the first region,

the first region is located between the top surface and the second region in the second direction,

the first region is covered with the side portion, and

the second region is exposed to the outside.

Clause 15.

The electronic device according to clause 14, wherein the terminal includes a second surface facing in the second direction, and

the second surface is exposed from the substrate.

Clause 16.

The electronic device according to clause 15, wherein the covering layer covers the second surface.

Clause 17.

The electronic device according to clause 16, wherein the side portion includes a first layer laminated on the side surface and a second layer laminated on the first layer, and the second layer contains a same metal as a metal contained in the covering layer.

REFERENCE NUMERALS

A10, A20, A30: Electronic device 10: Substrate
11: Mount surface 12: Reverse surface
13: End surface 21: Wiring layer
22: Terminal 221: First surface
222: Second surface 29: Conductive bonding layer
30: Electronic element 31: Semiconductor element
31A: Upper surface 311: Electrode
32: Passive element 321: Electrode
41: Pillar 41A: Peripheral surface
41B: Connection surface 411: First pillar
411A: Outer portion 411B: Inner portion
412: Second pillar 42: Shield
421: Top portion 422: Side portion
422A: First layer 422B: Second layer
50: Sealing resin 51: Top surface
52: Side surface 521: First region
522: Second region 60: Covering layer
81: Support member 82: Intermediate layer
83: First conductive layer 84: First resin layer
85: Second conductive layer 851: Base layer
852: Main layer 86: Second resin layer
861: Groove 88: Tape
891: First blade 892: Second blade
z: First direction x: Second direction
z: Third direction

1. An electronic device comprising:
a wiring layer;
an electronic element conductively bonded to the wiring layer;
a sealing resin covering the electronic element;
a pillar extending in a first direction and electrically connected to the wiring layer; and
a shield electrically connected to the pillar, wherein
the sealing resin includes a top surface facing in the first direction and located opposite to the wiring layer with respect to the electronic element in the first direction,
the shield covers at least a portion of the top surface,
the pillar includes a peripheral surface facing in a direction orthogonal to the first direction and a connection surface facing a same side as the top surface in the first direction,
the peripheral surface is covered with the sealing resin, and
the connection surface is in contact with the shield.

2. The electronic device according to claim 1, wherein the shield overlaps with the electronic element as viewed in the first direction.

3. The electronic device according to claim 2, wherein the shield covers an entirety of the top surface.

4. The electronic device according to claim 3, wherein the electronic element includes a semiconductor element,
the semiconductor element includes plurality of electrodes facing the wiring layer, and
the plurality of electrodes are conductively bonded to the wiring layer.

5. The electronic device according to claim 4, wherein the electronic element includes a passive element, and
a dimension in the first direction of the passive element is greater than a dimension in the first direction of the semiconductor element.

6. The electronic device according to claim 5, further comprising a bonding layer conductively bonding the wiring layer and the pillar.

7. The electronic device according to claim 4, wherein the pillar includes a portion of the electronic element.

8. The electronic device according to claim 7, wherein the pillar includes a first pillar included in a portion of the semiconductor element, and a second pillar including the connection surface and the peripheral surface and electrically connected to the first pillar, and
the first pillar is electrically connected to one of the plurality of electrodes.

9. The electronic device according to claim 4, further comprising a substrate supporting the wiring layer and the sealing resin.

10. The electronic device according to claim 9, further comprising a terminal electrically connected to the wiring layer, wherein
at least a portion of the terminal is housed in the substrate,
the terminal includes a first surface facing a side opposite to a side that faces the wiring layer in the first direction, and
the first surface is exposed from the substrate.

11. The electronic device according to claim 10, further comprising a covering layer that covers the first surface,
wherein the covering layer is an electrical conductor containing gold.

12. The electronic device according to claim 11, wherein the sealing resin includes a side surface facing in a second direction orthogonal to the first direction, and
the shield includes a top portion covering the top surface and a side portion connected to the top portion and covering a portion of the side surface.

13. The electronic device according to claim 12, wherein the side portion is spaced apart from the terminal.

14. The electronic device according to claim 13, wherein the side surface includes a first region connected to the top surface and a second region located opposite to the top surface with respect to the first region,
the first region is located between the top surface and the second region in the second direction,
the first region is covered with the side portion, and
the second region is exposed to the outside.

15. The electronic device according to claim 14, wherein the terminal includes a second surface facing in the second direction, and
the second surface is exposed from the substrate.

16. The electronic device according to claim 15, wherein the covering layer covers the second surface.

17. The electronic device according to claim 16, wherein the side portion includes a first layer laminated on the side surface and a second layer laminated on the first layer, and
the second layer contains a same metal as a metal contained in the covering layer.
